(19) United States
(12) Patent Application Publication
(10) Pub. No.: US 2026/0123263 A1
(43) Pub. Date: Apr. 30, 2026

(54) DISPLAY DEVICE, ELECTRONIC DEVICE, IMAGE INSPECTING DEVICE FOR DISPLAY DEVICE AND IMAGE INSPECTION METHOD OF DISPLAY DEVICE

(71) Applicant: Samsung Display Co., LTD., Yongin-si (KR)

(72) Inventor: Byung Kyu SON, Yongin-si (KR)

(21) Appl. No.: 19/256,473

(22) Filed: Jul. 1, 2025

(30) Foreign Application Priority Data
Oct. 25, 2024 (KR) 10-2024-0147199

(51) Int. Cl. H10K 59/88; H10H 29/856; H10K 59/80

(52) U.S. Cl. CPC H10K 59/88; H10H 29/856; H10K 59/878; H10K 59/879

(57) ABSTRACT

A display device includes: a display panel having a display area in which a plurality of pixels are disposed; a test element group portion disposed in a non-display area of the display panel and including a plurality of dummy pixels; and a lens disposed on the display panel, where the lens overlaps the display area and does not overlap the test element group portion.

This application claims priority to Korean Patent Application No. 10-2024-0147199 filed, on Oct. 25, 2024, and all the benefits accruing therefrom under 35 U.S.C. § 119, the content of which in its entirety is herein incorporated by reference.

### BACKGROUND

### 1. Technical Field

Embodiments of the present disclosure relate to a display device, and more particularly, to a display device, an electronic device, an image inspecting device for a display device and an image inspection method of a display device, which are capable of solving a collision problem between a wafer and a lens during a display panel inspection process and simplifying the inspection process.

### 2. Description of the Related Art

A head mounted display (HMD) is an image display device that is worn on a user's head in the form of glasses or helmets to form a focus at a close distance in front of the user's eyes. The head mounted display may implement virtual reality (VR) or augmented reality (AR).

The head mounted display may magnify an image displayed on a small display device by using a plurality of lenses, and display the magnified image. Therefore, the display device applied to the head mounted display needs to provide high-resolution images, for example, images with a resolution of 3000 Pixels Per Inch (PPI) or higher. To this end, an organic light emitting diode on silicon (OLEDoS), which is a high-resolution small organic light emitting display device, is used as the display device applied to the head mounted display. The OLEDoS is an image display device in which an organic light emitting diode (OLED) is disposed on a semiconductor wafer substrate on which a complementary metal oxide semiconductor (CMOS) is disposed.

### SUMMARY

Aspects of the present disclosure provide a display device, an electronic device, an image inspecting device for a display device, and an image inspection method of a display device, which are capable of solving a collision problem between a wafer and a lens during a display panel inspection process and simplifying the inspection process.

According to one embodiment of the present disclosure, there is provided a display device including: a display panel having a display area in which a plurality of pixels are disposed; a test element group portion disposed in a non-display area of the display panel and including a plurality of dummy pixels; and a lens disposed on the display panel, where the lens overlaps the display area and does not overlap the test element group portion.

According to one embodiment of the present disclosure, there is provided an electronic device including a display device providing a screen, where the display device includes: a display panel having a display area in which a plurality of pixels are disposed; a test element group portion disposed in a non-display area of the display panel and including a plurality of dummy pixels; and a lens disposed on the display panel, where the lens overlaps the display area and does not overlap the test element group portion.

According to one embodiment of the present disclosure, there is provided an image inspecting device for a display device, including: a translucent mirror; a micromirror array lens module for receiving light from a display panel through the translucent mirror; an imaging module for receiving light reflected from the micromirror array lens module and generating an image based on the received light; and a controller for controlling a mirror lens of the micromirror array lens module based on a chief ray angle preset according to a type of the display panel, wherein the mirror lens includes a plurality of micromirrors disposed to surround a center of the mirror lens, and the controller controls positions and angles of the plurality of micromirrors based on the chief ray angle preset according to the type of the display panel.

According to one embodiment of the present disclosure, there is provided an image inspection method of a display device, including: preparing a wafer having a plurality of display panels and a plurality of test element group portions disposed to correspond to the plurality of display panels, respectively; disposing an image inspecting device on each of the test element group portions; controlling a mirror lens of the image inspecting device based on a chief ray angle preset according to a type of a display panel of the plurality of display panels corresponding to each of the test element group portion; imaging each of the test element group portion using the image inspecting device with the mirror lens controlled; and determining whether the display panel is defective based on an image captured by the image inspecting device.

In accordance with the display device, the electronic device, the image inspecting device for a display device, and the image inspection method of a display device according to one embodiment, it is possible to solve a collision problem between a wafer and a lens during a display panel inspection process and simplify the inspection process.

For example, since the image inspecting device of one embodiment includes a micromirror array lens module corresponding to a pancake lens, image inspection of the display panel may be performed without a lens (e.g., a pancake lens). In this case, the image inspecting device may image dummy pixels of a test element group portion of the display panel. Accordingly, an alignment operation between the display panel and the lens may not be required, and the collision problem between the display panel and the lens, which may occur during the alignment operation between the display panel and the lens, may be solved.

In addition, since the micromirror array lens module of the image inspecting device of one embodiment includes a mirror lens, which may be controlled based on a chief ray angle set according to the type of the display panel, image inspection of the display panel may be performed without the need to prepare various lenses for each type of display panel.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is an exploded perspective view showing a display device according to one embodiment;

FIG. 2 is a block diagram illustrating a display device according to one embodiment;

FIG. 3 is an equivalent circuit diagram of a first sub-pixel according to one embodiment;

FIG. 4 is a layout diagram illustrating an example of a display panel according to one embodiment;

FIG. 5 is a layout diagram showing an example of the display area of FIG. 4;

FIG. 6 is a layout diagram showing another example of the display area of FIG. 4;

FIG. 7 is a cross-sectional view illustrating an example of a display panel taken along line I1-I1′ of FIG. 5;

FIG. 8 is a cross-sectional view of a display device according to one embodiment;

FIG. 9 is a schematic plan view showing a detailed configuration of a test element group portion of FIG. 4;

FIG. 10 is a diagram showing an image inspecting device according to one embodiment;

FIG. 11 is a diagram for describing an image inspection method of a display device according to one embodiment;

FIG. 12 is a diagram illustrating a mirror lens of a micromirror array lens module of FIG. 11;

FIG. 13 is a diagram showing an image of the test element group portion acquired through the image inspecting device of FIG. 10;

FIG. 14 shows enlarged views of a first area, a second area, and a third area in the image of FIG. 13;

FIG. 15 is a diagram illustrating the arrangement position of the test element group portion according to another embodiment; and

FIG. 16 is a perspective view showing an electronic device to which a display device according to one embodiment is applied.

FIG. 17 is a block diagram of an electronic device according to one embodiment.

FIGS. 18, 19 and 20 are schematic diagrams of electronic devices according to various embodiments.

### DETAILED DESCRIPTION

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Various embodiments can be practiced individually or in combination.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof. Hereinafter, specific exemplary embodiments will be described with reference to the accompanying drawings.

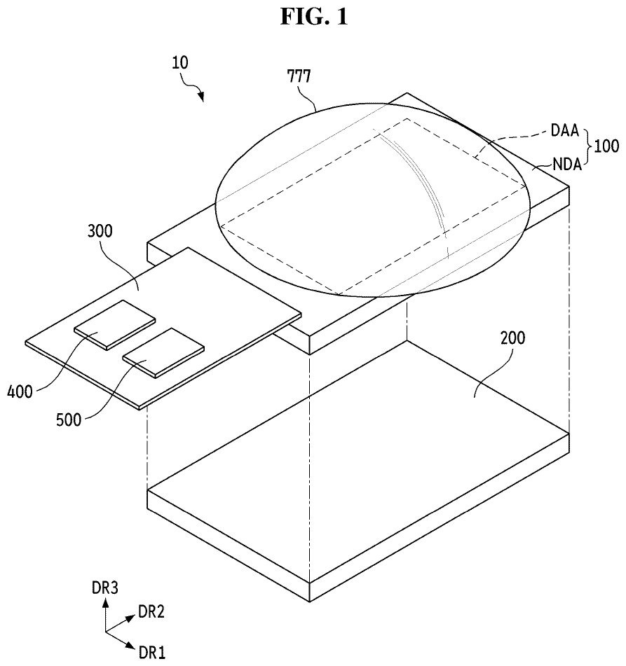

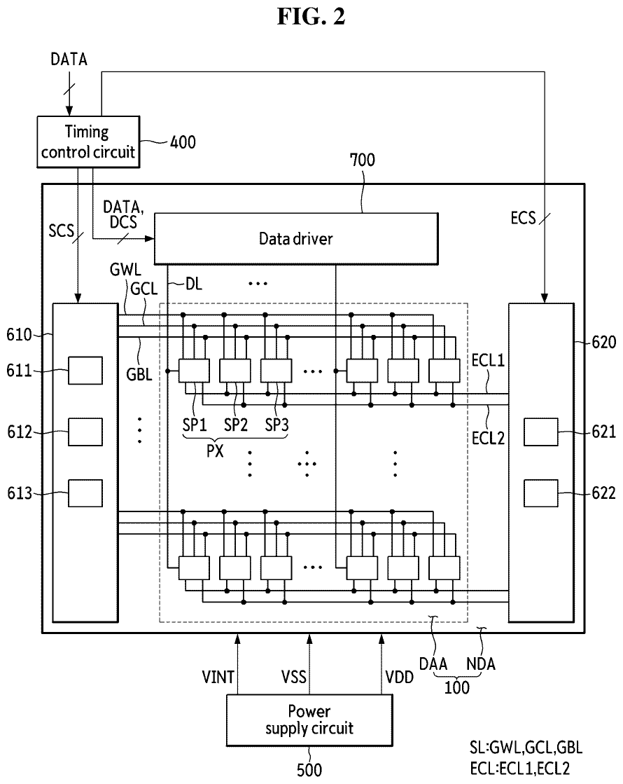

FIG. 1 is an exploded perspective view showing a display device according to one embodiment. FIG. 2 is a block diagram illustrating a display device according to one embodiment.

Referring to FIGS. 1 and 2, a display device 10 according to one embodiment is a device displaying a moving image or a still image. The display device 10 according to one embodiment may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 according to one embodiment may be applied as a display unit of a television, a laptop, a monitor, a billboard, or an Internet-of-Things (IoT) terminal. Alternatively, the display device 10 according to one embodiment may be applied to a smart watch, a watch phone, a head mounted display (HMD) for implementing virtual reality and augmented reality, and the like.

The display device 10 according to one embodiment may include a display panel 100, a heat dissipation layer 200, a circuit board 300, a timing control circuit 400, a power supply circuit 500, and a first lens 777.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

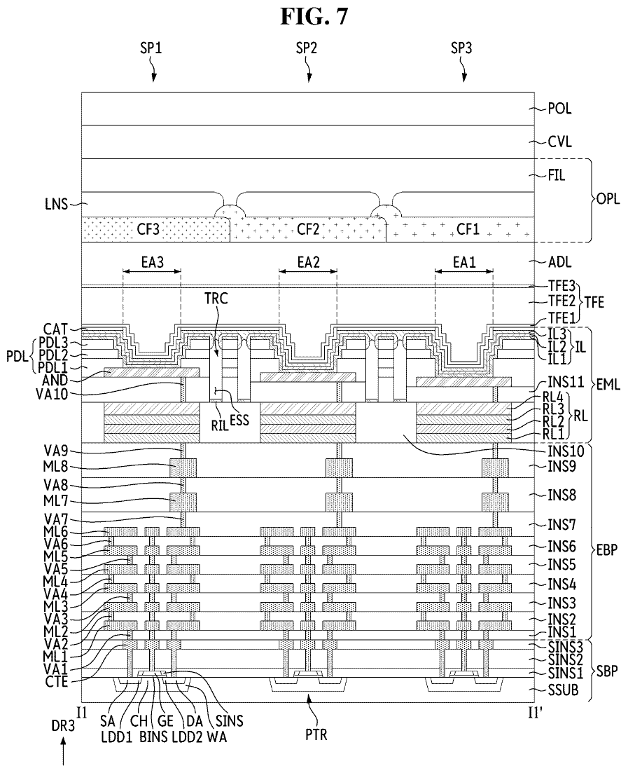

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image. For example, a substrate (e.g., a semiconductor substrate SSUB of FIG. 7) of the display panel 100 may include the display area DAA and the non-display area NDA.

The plurality of pixels PX may be disposed in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines ECL1 and a plurality of second emission control lines ECL2.

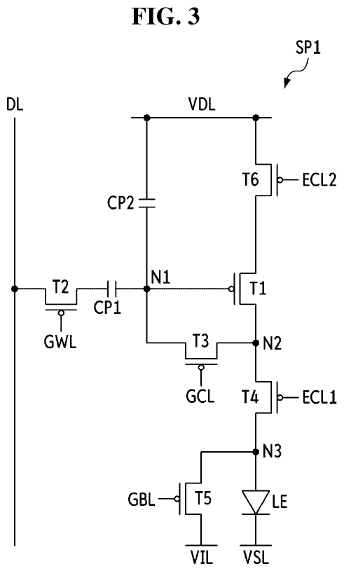

The plurality of pixels PX may include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and disposed on the semiconductor substrate SSUB (see FIG. 7). For example, the plurality of pixel transistors of the data driver 700 may be formed of complementary metal oxide semiconductor (CMOS), but the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 may include a plurality of scan transistors, and the emission driver 620 may include a plurality of light emitting transistors. The plurality of scan transistors and the plurality of light emitting transistors may be formed on the semiconductor substrate SSUB (see FIG. 7) through a semiconductor process. For example, the plurality of scan transistors and the plurality of light emitting transistors may be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed of CMOS, but the present disclosure is not limited thereto.

The data driver 700 may receive digital video data DATA and a data timing control signal DCS from the timing control circuit 400. The data driver 700 may convert the digital video data DATA into analog data voltages according to the data timing control signal DCS and output the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 may serve to dissipate heat generated from the display panel 100. The heat dissipation layer 200 may include a metal layer having high thermal conductivity, such as graphite, silver (Ag), copper (Cu), or aluminum (Al).

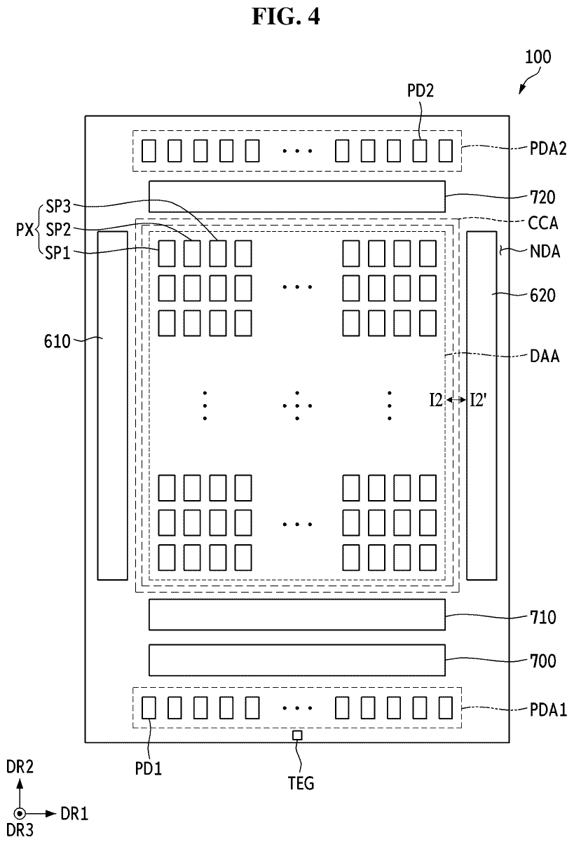

The circuit board 300 may be electrically connected to a plurality of first pads PD1 (see FIG. 4) of a first pad portion PDA1 (see FIG. 4) of the display panel 100 by using a conductive adhesive member such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed of CMOS, but the present disclosure is not limited thereto. Each of the timing control circuit 400 and the power supply circuit 500 may be disposed between the data driver 700 and the first pad portion PDA1 (see FIG. 4).

The first lens 777 may be disposed on the display panel 100. For example, the first lens 777 may be disposed on the display panel 100 so as to overlap the display area DAA of the display panel 100. The first lens 777 may overlap the entire display area DAA. For example, in a plan view, the first lens 777 may surround the edge of the display area DAA. The first lens 777 may have a hemispherical shape. The first lens may include, for example, a pancake lens.

FIG. 3 is an equivalent circuit diagram of a first sub-pixel according to one embodiment.

Referring to FIG. 3, a first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors T1 to T6, a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the present disclosure is not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as “driving current”) flowing between the source electrode and the drain electrode thereof according to a voltage applied to the gate electrode thereof.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed between a first node N1 and a second node N2. The third transistor T3 may be turned on by the write control signal of the write control line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 may be turned on by the first emission control signal of the first emission control line ECL1 to connect the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be disposed between the source electrode of the first transistor T1 and the second driving voltage line VDL. The sixth transistor T6 may be turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 may not be repeated in the present disclosure.

FIG. 4 is a layout diagram illustrating an example of a display panel according to one embodiment.

Referring to FIG. 4, the display area DAA of the display panel 100 according to one embodiment may include the plurality of pixels PX arranged in a matrix form. The non-display area NDA of the display panel 100 according to one embodiment may include the scan driver 610, the emission driver 620, the data driver 700, a first distribution circuit 710, a second distribution circuit 720, the first pad portion PDA1, a second pad portion PDA2, and a test element group portion TEG.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2.

The second distribution circuit 720 may distribute signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2.

A cathode connection portion CCA may be a region in which a second electrode CAT (see FIG. 7) of a display element layer EML (see FIG. 7) is connected to the first driving voltage line VSL of the non-display area NDA. The cathode connection portion CCA may be disposed outside at least one side of the display area DAA. For example, the cathode connection portion CCA may be disposed outside at least on one side among the left side, the right side, the upper side, and the lower side of the display area DAA. Alternatively, the cathode connection portion CCA may be disposed to surround the display area DAA as shown in FIG. 4 in order to minimize a deviation in the first driving voltage VSS due to a voltage drop (IR drop) or voltage rise (IR rising) of the second electrode CAT in the display area DAA.

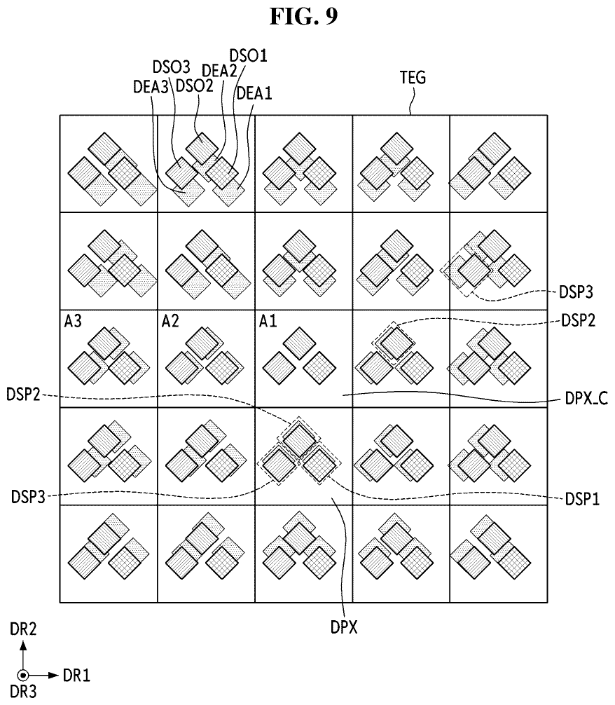

A test element group portion TEG may be disposed in the non-display area NDA of the display panel (or substrate). For example, the test element group portion TEG may be disposed in the non-display area NDA between the first pad portion PDA1 and the edge of the display panel 100. The test element group portion TEG may include a plurality of dummy pixels DPX (see FIG. 9). The test element group portion TEG may not overlap the first lens 777 in a plan view. For example, while the pixels PX in the display area DAA overlap the first lens 777, the dummy pixels DPX in the test element group portion TEG may not overlap the first lens 777 in a plan view.

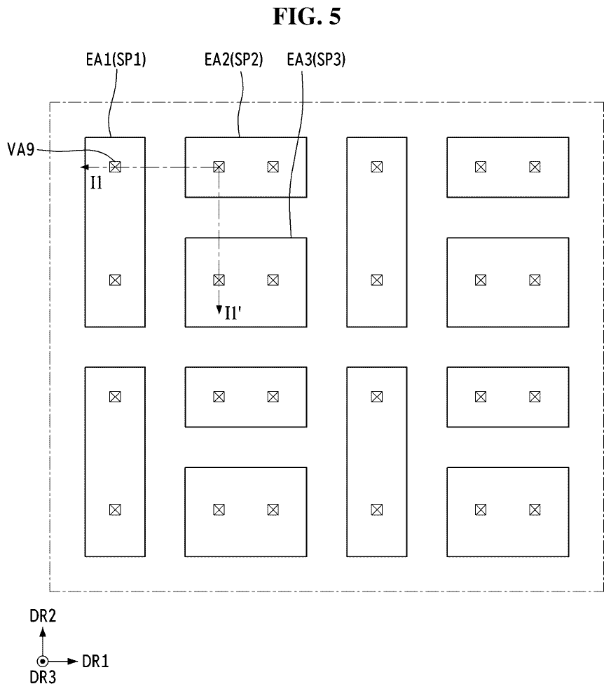

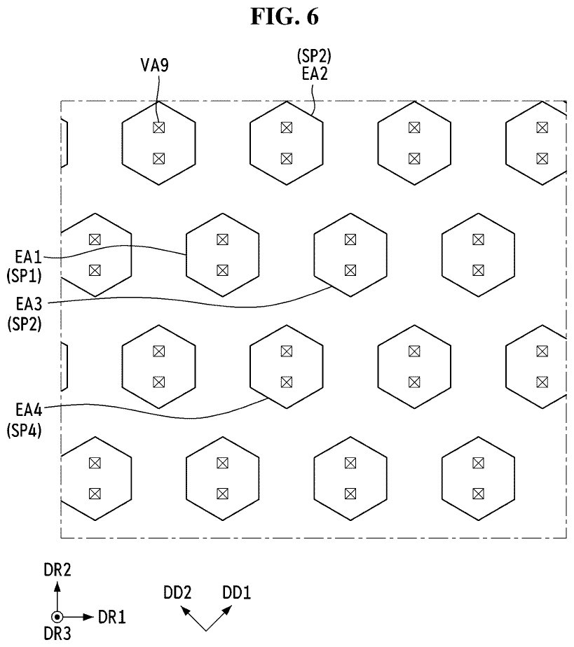

FIG. 5 is a layout diagram showing an example of the display area of FIG. 4. FIG. 6 is a layout diagram showing another example of the display area of FIG. 4.

Referring to FIGS. 5 and 6, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in a plan view, a quadrilateral or hexagonal shape as shown in FIGS. 5 and 6, but the present disclosure is not limited thereto. The first emission area EA1, the second emission area EA2, and the third emission area EA3 may have a polygonal shape other than a quadrangle or hexagon, a circular shape, an elliptical shape, or an atypical shape in a plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 6, the emission areas EA1, EA2, EA3, and EA4 may have a hexagonal shape in a plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to 460 nm, the green wavelength band may be a wavelength band of light whose main peak wavelength is in the range of approximately 480 nm to 560 nm, and the red wavelength band may be a wavelength band of light whose main peak wavelength is in the range of approximately 600 nm to 750 nm.

Each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombus shape, or a hexagonal structure in which the emission areas each having a hexagonal shape are arranged as shown in FIG. 6.

FIG. 7 is a cross-sectional view illustrating an example of a display panel taken along line I1-I1′ of FIG. 5.

Referring to FIG. 7, the display panel 100 may include a semiconductor backplane SBP, a light emitting element backplane EBP, a display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating layer BINS may be disposed between a gate electrode GE and the well region WA. A side insulating layer SINS may be disposed on the side surface of the gate electrode GE. The side insulating layer SINS may be disposed on the lower insulating layer BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating layer BINS. The second low-concentration impurity region LDD2 may be a region having a lower impurity concentration than the drain region DA due to the lower insulating layer BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating layer SINS1 may be disposed on the semiconductor substrate SSUB. A second semiconductor insulating layer SINS2 may be disposed on the first semiconductor insulating layer SINS1.

The plurality of contact terminals CTE may be disposed on the second semiconductor insulating layer SINS2. Each of the plurality of contact terminals CTE may be connected to any one of the gate electrode GE, the source region SA, and the drain region DA of each of the pixel transistors PTR through a hole penetrating the first semiconductor insulating layer SINS1 and the second semiconductor insulating layer INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating layer SINS3 may be disposed on a side surface of each of the plurality of contact terminals CTE. The top surface of each of the plurality of contact terminals CTE may be exposed without being covered by the third semiconductor insulating layer SINS3.

Each of the first semiconductor insulating layer SINS1, the second semiconductor insulating layer SINS2, and the third semiconductor insulating layer SINS3 may be formed of silicon carbonitride (SiCN) or a silicon oxide (SiOx)-based inorganic film, but the present disclosure is not limited thereto.

The semiconductor substrate SSUB may be replaced with a glass substrate or a polymer resin substrate such as polyimide. In this case, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP may include a plurality of conductive layers ML1 to ML8, a plurality of vias VA1 to VA9, and a plurality of insulating layers INS1 to INS11. In addition, the light emitting element backplane EBP may include a plurality of insulating layers INS1 to INS9 disposed between the first to eighth conductive layers ML1 to ML8.

The first to eighth insulating layers INS1 to INS8 may serve to insulate the first to eighth conductive layers ML1 to ML8. The first to eighth conductive layers ML1 to ML8 may serve to connect the plurality of contact terminals CTE exposed from the semiconductor backplane SBP to thereby implement the circuit of the first sub-pixel SP1 shown in FIG. 3.

For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating layers INS1 to INS8 may be formed of a silicon oxide (SiOx)-based inorganic film, but the present disclosure is not limited thereto.

A ninth insulating layer INS9 may be disposed on the eighth insulating layer INS8 and the eighth conductive layer ML8. The ninth insulating layer INS9 may be formed of a silicon oxide (SiOx)-based inorganic film, but the present disclosure is not limited thereto.

Each of the ninth vias VA9 may penetrate the ninth insulating layer INS9 and be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

The display element layer EML may be disposed on the light emitting element backplane EBP. The display element layer EML may include tenth and eleventh insulating layers INS10 and INS11, a reflective electrode RL, the first electrodes AND, a light emitting stack IL, the second electrode CAT, a pixel defining film PDL, and a plurality of trenches TRC.

The reflective electrode RL may be disposed on the ninth insulating layer INS9. The reflective electrode RL may include at least one reflective electrode RL1, RL2, RL3, and RL4. For example, the reflective electrode RL may include the first to fourth reflective electrodes RL1, RL2, RL3, and RL4 as shown in FIG. 7.

The first reflective electrodes RL1 may be disposed on the ninth interlayer insulating layer INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth interlayer insulating layer INS10 may be disposed on the ninth interlayer insulating layer INS9. The tenth interlayer insulating layer INS10 may be disposed between the reflective electrodes RL adjacent to each other. The tenth interlayer insulating layer INS10 may be a film for flattening a stepped portion caused by the reflective electrodes RL. The eleventh interlayer insulating layer INS11 may be disposed on the tenth interlayer insulating layer INS10 and the reflective electrode RL.

The tenth interlayer insulating layer INS10 and the eleventh interlayer insulating layer INS11 may be formed of a silicon oxide (SiOx)-based inorganic film, but the embodiment of the present disclosure is not limited thereto.

The eleventh interlayer insulating layer INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating layer INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating layer INS11 may be set for each of the first sub-pixel SP1, the second sub-pixel SP2, and the third sub-pixel SP3.

For example, as shown in FIG. 7, the thickness of the eleventh interlayer insulating layer INS11 in the first sub-pixel SP1 may be greater than the thickness of the eleventh interlayer insulating layer INS11 in the second sub-pixel SP2, and the thickness of the eleventh interlayer insulating layer INS11 in the second sub-pixel SP2 may be greater than the thickness of the eleventh interlayer insulating layer INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating layer INS11 and be connected to the exposed ninth metal layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating layer INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film. Alternatively, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating layer INS11 may be partially recessed at each of the plurality of trenches TRC.

At least one trench TRC may be disposed between the neighboring sub-pixels SP1, SP2, and SP3. Although FIG. 7 illustrates that two trenches TRC are disposed between the neighboring sub-pixels SP1, SP2, and SP3, the present disclosure is not limited thereto.

The light emitting stack IL may include a plurality of stack layers IL1, IL2, and IL3. FIG. 7 illustrates that the light emitting stack IL has a three-tandem structure including a first stack layer IL1, a second stack layer IL2, and a third stack layer IL3, but the present disclosure is not limited thereto. For example, the light emitting stack IL may have a two-tandem structure including two stack layers.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film RIL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer disposed between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, another structure may exist instead of the trench TRC. For example, instead of the trench TRC, a reverse tapered partition wall may be disposed on the pixel defining film PDL.

In addition, FIG. 7 illustrates that the light emitting stack IL that emits light is disposed in the first emission area EA1, the second emission area EA2, and the third emission area EA3, but the present disclosure is not limited thereto. For example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In this case, first to third color filters CF1, CF2, and CF3 of the optical layer OPL may be omitted.

The second electrode CAT may be disposed on the light emitting stack IL. The second electrode CAT may be disposed on the third stack layer IL3 in each of the plurality of trenches TRC. The second electrode CAT may be formed of a transparent conductive material (TCO) such as ITO or IZO that can transmit light or a semi-transmissive conductive material such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce or prevent oxygen or moisture from permeating into the display element layer EML. The first encapsulation inorganic film TFE1 may be disposed on the second electrode CAT, and the second encapsulation inorganic film TFE2 may be disposed on the first encapsulation inorganic film TFE1. The first encapsulation inorganic film TFE1 and the second encapsulation inorganic film TFE3 may be formed of multiple layers in which one or more inorganic films of silicon nitride (SiNₓ), silicon oxynitride (SiON), silicon oxide (SiOₓ), titanium oxide (TiOₓ), and aluminum oxide (AlOₓ) layers are alternately stacked.

In addition, the encapsulation layer TFE may include at least one organic film to protect the display element layer EML from foreign substances such as dust. The at least one organic film of the encapsulation layer TFE may be disposed between the first encapsulation inorganic film TFE1 and the second encapsulation inorganic film TFE2. The at least one organic film of the encapsulation layer TFE may be a monomer. Alternatively, at least one organic film of the encapsulation layer TFE may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL may include a plurality of color filters CF1, CF2, and CF3, a plurality of second lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of second lenses LNS may be disposed on the first color filter CF1, the second color filter CF2, and the third color filter CF3, respectively. Each of the plurality of second lenses LNS may be a structure for increasing the proportion of light directed to the front of the display device 10. Each of the plurality of second lenses LNS may have a cross-sectional shape that is convex in an upward direction (i.e., third direction DDR3). Each of the plurality of second lenses LNS may include a microlens.

The filling layer FIL may be disposed on the plurality of second lenses LNS. The filling layer FIL may have a predetermined refractive index such that light travels in the third direction DR3 at an interface between the filling layer FIL and the plurality of second lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be disposed on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

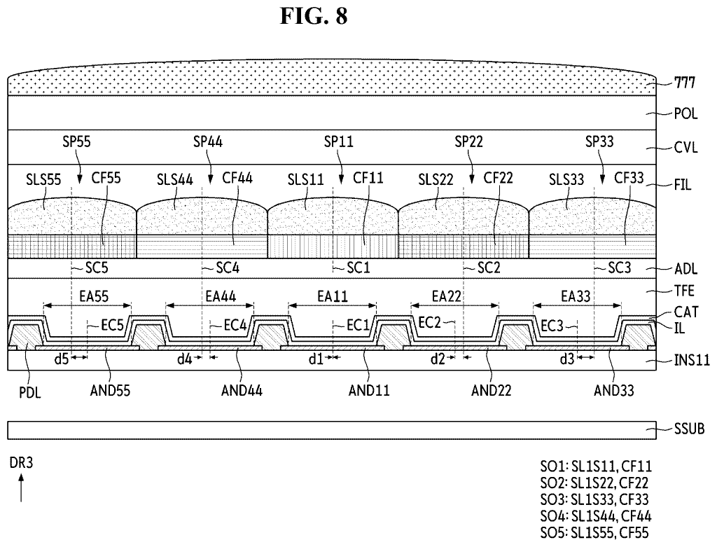

FIG. 8 is a cross-sectional view of a display device according to one embodiment.

The display device of FIG. 8 is different from the display device of FIG. 7 described above in the arrangement position of a color filter and a second lens with respect to an emission area in a sub-pixel, and the difference will be mainly described as follows.

As shown in FIG. 8, the first lens 777 may be disposed on the polarizing plate POL so as to overlap a plurality of sub-lenses SLS11, SLS22, SLS33, SLS44, and SLS55 in a plan view.

Five sub-pixels SP11, SP22, SP33, SP44, and SP55 are illustrated in FIG. 8. For example, the first sub-pixel SP11, the second sub-pixel SP22, the third sub-pixel SP33, the fourth sub-pixel SP44, and the fifth sub-pixel SP55 are illustrated in FIG. 8. Each of the sub-pixels SP11, SP22, SP33, SP44, and SP55 may include a first electrode (hereinafter, referred to as anode electrode), the light emitting stack IL, the second electrode CAT (hereinafter, referred to as cathode electrode CAT), a color filter, and a second lens (hereinafter, referred to as sub-lens). Here, the plurality of sub-lenses SLS11, SLS22, SLS33, SLS44, and SLS55 may correspond to the second lenses LNS in FIG. 7.

The first sub-pixel SP11, the second sub-pixel SP22, the third sub-pixel SP33, the fourth sub-pixel SP44, and the fifth sub-pixel SP55 may be disposed in different pixels. For example, when defining five different pixels as a first pixel, a second pixel, a third pixel, a fourth pixel, and a fifth pixel, respectively, the first sub-pixel SP11 may be any one of three sub-pixels disposed in the first pixel, the second sub-pixel SP22 may be any one of three sub-pixels disposed in the second pixel, the third sub-pixel SP33 may be any one of three sub-pixels disposed in the third pixel, the fourth sub-pixel SP44 may be any one of three sub-pixels disposed in the fourth pixel, and the fifth sub-pixel SP55 may be any one of the three sub-pixels disposed in the fifth pixel. In this case, the sub-pixels may correspond to each other. For example, the first sub-pixel SP11 of the first pixel, the second sub-pixel SP22 of the second pixel, the third sub-pixel SP33 of the third pixel, the fourth sub-pixel SP44 of the fourth pixel, and the fifth sub-pixel SP55 of the fifth pixel may include color filters of the same color.

The first sub-pixel SP11 may include a first emission area EA11, a first anode electrode AND11, the light emitting stack IL, the cathode electrode CAT, a first color filter CF11, and a first sub-lens SLS11. Here, the light emitting stack IL of the first sub-pixel SP11 may mean the light emitting stack IL between the first anode electrode AND11 and the cathode electrode CAT. The first color filter CF11 and the first sub-lens SLS11 may overlap each other.

The second sub-pixel SP22 may include a second emission area EA22, a second anode electrode AND22, the light emitting stack IL, the cathode electrode CAT, a second color filter CF22, and a second sub-lens SLS22. Here, the light emitting stack IL of the second sub-pixel SP22 may mean the light emitting stack IL between the second anode electrode AND22 and the cathode electrode CAT. The second color filter CF22 and the second sub-lens SLS22 may overlap each other.

The third sub-pixel SP33 may include a third emission area EA33, a third anode electrode AND33, the light emitting stack IL, the cathode electrode CAT, a third color filter CF33, and a third sub-lens SLS33. Here, the light emitting stack IL of the third sub-pixel SP33 may mean the light emitting stack IL between the third anode electrode AND33 and the cathode electrode CAT. The third color filter CF33 and the third sub-lens SLS33 may overlap each other.

The fourth sub-pixel SP44 may include a fourth emission area EA44, a fourth anode electrode AND44, the light emitting stack IL, the cathode electrode CAT, a fourth color filter CF44, and a fourth sub-lens SLS44. Here, the light emitting stack IL of the fourth sub-pixel SP44 may mean the light emitting stack IL between the fourth anode electrode AND44 and the cathode electrode CAT. The fourth color filter CF44 and the fourth sub-lens SLS44 may overlap each other.

The fifth sub-pixel SP55 may include a fifth emission area EA55, a fifth anode electrode AND55, the light emitting stack IL, the cathode electrode CAT, a fifth color filter CF55, and a fifth sub-lens SLS55. Here, the light emitting stack IL of the fifth sub-pixel SP55 may mean the light emitting stack IL between the fifth anode electrode AND55 and the cathode electrode CAT. The fifth color filter CF55 and the fifth sub-lens SLS55 may overlap each other.

The first sub-pixel SP11 may be disposed at the center of the display panel 100 (or the display area DAA of the display panel 100, or the first lens 777). For example, the first sub-pixel SP11 may overlap the center of the first lens 777. Specifically, the center of the first anode electrode AND11, the center of the first emission area EA11, the center of the first color filter CF11, and the center of the first lens 777 may overlap each other. Here, the first sub-pixel SP11 may be defined as a central sub-pixel.

The second to fifth sub-pixels SP22 to SP55 may be sequentially disposed on one side or the other side of the first sub-pixel SP11 with respect to the first sub-pixel SP11. For example, the second sub-pixel SP22 and the third sub-pixel SP33 may be sequentially disposed on one side of the first sub-pixel SP11, and the fourth sub-pixel SP44 and the fifth sub-pixel SP55 may be sequentially disposed on the other side of the first sub-pixel SP11. Here, the second to fifth sub-pixels SP22 to SP55 may be defined as peripheral sub-pixels.

Here, a color filter and a sub-lens included in one sub-pixel are collectively defined as a “sub-optical layer” of the one sub-pixel. A center SC1 of a sub-optical layer (i.e., sub-optical layer SO1) of the central sub-pixel (e.g., the first sub-pixel SP11) disposed at the center of the display panel 100 (or at the center of the display area DAA, or at the center of the first lens 777) may overlap a center EC1 of the first emission area EA11 of the central sub-pixel (e.g., the first sub-pixel SP11) in a plan view.

Meanwhile, the center of a sub-optical layer of a peripheral sub-pixel does not overlap the center of an emission area of that peripheral sub-pixel in a plan view. To this end, the sub-optical layer of the peripheral sub-pixel may be shifted by a predetermined distance toward the edge of the display panel 100 (or the display area DAA of the display panel 100, or the first lens 777) with respect to the center of the emission area of the peripheral sub-pixel. For example, the sub-optical layer (SO2 or a center SC2 of the sub-optical layer) of the second sub-pixel SP22 may be shifted by a predetermined distance (i.e., shift distance d2) toward the edge of the display panel 100 (or the display area DAA of the display panel 100, or the first lens 777) with respect to a center EC2 of the second emission area EA22 in a direction perpendicular to the third direction DR3; the sub-optical layer (SO3 or a center SC3 of the sub-optical layer) of the third sub-pixel SP33 may be shifted by a predetermined distance (i.e., shift distance d3) toward the edge of the display panel 100 (or the display area DAA of the display panel 100, or the first lens 777) with respect to a center EC3 of the third emission area EA33 in the same direction as the shifted direction of the center EC2; the sub-optical layer (SO4 or a center SC4 of the sub-optical layer) of the fourth sub-pixel SP44 may be shifted by a predetermined distance (i.e., shift distance d4) toward the edge of the display panel 100 (or the display area DAA of the display panel 100, or the first lens 777) with respect to a center EC4 of the fourth emission area EA44 in a direction opposite to the shifted direction of the center EC2; and the sub-optical layer (SO5 or a center SC5 of the sub-optical layer) of the fifth sub-pixel SP55 may be shifted by a predetermined distance (i.e., shift distance d5) toward the edge of the display panel 100 (or the display area DAA of the display panel 100, or the first lens 777) with respect to a center EC5 of the fifth emission area EA55 in the same direction as the shifted direction of the center EC4.

The sub-optical layer of the peripheral sub-pixel may be shifted by a larger magnitude with an increase of its distance from the central sub-pixel. For example, between the second sub-pixel SP22 and the third sub-pixel SP33 sequentially disposed on one side of the first sub-pixel SP11, the third sub-pixel SP33 disposed relatively farther from the first sub-pixel SP11 may include a sub-optical layer SO3 shifted by a larger magnitude than the sub-optical layer SO2 of the second sub-pixel SP22. As another example, between the fourth sub-pixel SP44 and the fifth sub-pixel SP55 sequentially disposed on the other side of the first sub-pixel SP11, the fifth sub-pixel SP55 disposed relatively farther from the first sub-pixel SP11 may include a sub-optical layer SO5 shifted by a larger magnitude than that the sub-optical layer SO4 of the fourth sub-pixel SP44.

In other words, the sub-pixels SP11 to SP55 may include the sub-optical layers shifted by larger magnitudes as they are located farther from the center of the display panel 100 (or the display area DAA of the display panel 100, or the first lens 777). For example, when the distance between the center of the emission area of the sub-pixel and the center of the sub-optical layer of that sub-pixel is defined as a “shift distance” of that sub-pixel (or a shift distance of the sub-optical layer of that sub-pixel), a shift distance d1 of the first sub-pixel SP11 may be substantially zero; a shift distance d3 of the third sub-pixel SP33 may be greater than a shift distance d2 of the second sub-pixel SP22; and a shift distance d5 of the fifth sub-pixel SP55 may be greater than a shift distance d4 of the fourth sub-pixel SP44.

As the sub-pixels SP11 to SP55 include the sub-optical layers shifted by the larger magnitudes as they are located farther from the center of the display panel 100 (or the display area DAA of the display panel 100, or the first lens 777) as described above, light at the edge of the first lens 777 may be emitted to the outside while satisfying a chief ray angle (“CRA”). Here, the chief ray angle may be an angle between chief ray and an optical axis.

Meanwhile, the constituent components between the semiconductor substrate SSUB and the eleventh insulating layer INS11 of FIG. 7 may also be disposed between the substrate SSUB (e.g., the semiconductor substrate SSUB) and the eleventh insulating layer INS11 of FIG. 8.

Also, the pixel defining film PDL of FIG. 8 may include the first pixel defining film PDL1, the second pixel defining film PDL2, and the third pixel defining film PDL3 of FIG. 7.

In addition, the light emitting stack IL of FIG. 8 may include the first stack layer IL1, the second stack layer IL2, and the third stack layer IL3 of FIG. 7.

Moreover, the encapsulation layer TFE of FIG. 8 may include the first encapsulation inorganic film TFE1, the encapsulation organic film TFE2, and the second encapsulation inorganic film TFE3 of FIG. 7.

FIG. 9 is a schematic plan view showing a detailed configuration of the test element group portion TEG of FIG. 4.

As shown in FIG. 9, the test element group portion TEG may include the plurality of dummy pixels DPX. FIG. 9 illustrates that the test element group portion TEG may include twenty five dummy pixels DPX. However, the number of dummy pixels DPX of the test element group portion TEG is not limited thereto and may be variously changed. Meanwhile, the number of dummy pixels DPX of the test element group portion TEG may be less than the number of pixels PX of the display area DAA.

The dummy pixels DPX of the test element group portion TEG may be formed together with the pixels PX of the display area DAA in the same process. The dummy pixel DPX of the test element group portion TEG may have the same configuration and size as the pixel PX of the display area DAA. Therefore, the detailed description of the dummy pixel DPX is substituted with the description of the pixel PX.

The dummy pixel DPX may include a first dummy sub-pixel DSP1, a second dummy sub-pixel DSP2, and a third dummy sub-pixel DSP3.

The first dummy sub-pixel DSP1 may have the same configuration and size as the aforementioned first sub-pixel (e.g., the first sub-pixels SP1 and SP11). Therefore, the detailed description of the first dummy sub-pixel DSP1 is substituted with the description of the aforementioned first sub-pixels SP1 and SP11.

The second dummy sub-pixel DSP2 may have the same configuration and size as the aforementioned second sub-pixel (e.g., the second sub-pixels SP2 and SP22). Therefore, the detailed description of the second dummy sub-pixel DSP2 is substituted with the description of the aforementioned second sub-pixel (e.g., the second sub-pixels SP2 and SP22).

The third dummy sub-pixel DSP3 may have the same configuration and size as the aforementioned third sub-pixel (e.g., the third sub-pixels SP3 and SP33). Accordingly, the detailed description of the third dummy sub-pixel DSP3 is substituted with the description of the aforementioned third sub-pixel (e.g., the third sub-pixels SP3 and SP33).

The first dummy sub-pixel DSP1 may include a first dummy emission area DEA1 and a first dummy sub-optical layer DSO1. The first dummy sub-pixel DSP1 may provide light through the first dummy emission area DEA1. The first dummy sub-optical layer DSO1 may include a first dummy color filter (not shown) and a first dummy sub-lens (not shown) disposed to overlap each other in a plan view. Since the first dummy emission area DEA1, the first dummy sub-optical layer DSO1, the first dummy color filter, and the first dummy sub-lens of the first dummy sub-pixel DSP1 are the same as the first emission area EA11, the first sub-optical layer, the first color filter CF11, and the first sub-lens SLS11 of the first sub-pixel SP11 described above regarding FIG. 8, respectively, the description of the first dummy emission area DEA1, the first dummy sub-optical layer DSO1, the first dummy color filter, and the first dummy sub-lens is substituted with the description of the first emission area EA11, the first sub-optical layer, the first color filter CF11, and the first sub-lens SLS11 of the first sub-pixel SP11 described above.

The second dummy sub-pixel DSP2 may include a second dummy emission area DEA2 and a second dummy sub-optical layer DSO2. The second dummy sub-pixel DSP2 may provide light through the second dummy emission area DEA2. The second dummy sub-optical layer DSO2 may include a second dummy color filter and a second dummy sub-lens disposed to overlap each other. Since the second dummy emission area DEA2, the second dummy sub-optical layer DSO2, the second dummy color filter, and the second dummy sub-lens of the second dummy sub-pixel DSP2 are the same as the second emission area EA22, the second sub-optical layer, the second color filter CF22, and the second sub-lens SLS22 of the second sub-pixel SP22 described above, respectively, the description of the second dummy emission area DEA2, the second dummy sub-optical layer DSO2, the second dummy color filter, and the second dummy sub-lens is substituted with the description of the second emission area EA22, the second sub-optical layer, the second color filter CF22, and the second sub-lens SLS22 described above.

The third dummy sub-pixel DSP3 may include a third dummy emission area DEA3 and a third dummy sub-optical layer DSO3. The third dummy sub-pixel DSP3 may provide light through the third dummy emission area DEA3. The third dummy sub-optical layer DSO3 may include a third dummy color filter and a third dummy sub-lens disposed to overlap each other. Since the third dummy emission area DEA3, the third dummy sub-optical layer DSO3, the third dummy color filter, and the third dummy sub-lens of the third dummy sub-pixel DSP3 are the same as the third emission area EA33, the third sub-optical layer, the third color filter CF33, and the third sub-lens SLS33 of the third sub-pixel SP33 described above, respectively, the description of the third dummy emission area DEA3, the third dummy sub-optical layer DSO3, the third dummy color filter, and the third dummy sub-lens is substituted with the description of the third emission area EA33, the third sub-optical layer, the third color filter CF33, and the third sub-lens SLS33 described above.

When one dummy pixel DPX located at the center of the test element group portion TEG is defined as a central dummy pixel DPX_C, the first dummy sub-pixel DSP1 of the central dummy pixel DPX_C is defined as a central dummy sub-pixel, the remaining dummy pixels DPX of the test element group portion TEG except the central dummy pixel DPX_C are defined as peripheral dummy pixels, respectively, and the first dummy sub-pixel DSP1 of the peripheral dummy sub-pixel DPX is defined as a peripheral dummy sub-pixel, the dummy sub-optical layer of the peripheral dummy sub-pixel may be shifted by a larger magnitude with an increase of its distance from the central dummy sub-pixel. In this case, the peripheral dummy sub-pixel and the central dummy sub-pixel may be corresponding dummy sub-pixels that have color filters of the same color. In this way, just as the sub-optical layer of the peripheral sub-pixel is shifted by a larger magnitude with an increase of its distance from the central sub-pixel in the display area DAA, the dummy sub-optical layer of the peripheral dummy sub-pixel may be shifted by a larger magnitude with an increase of its distance from the central dummy sub-pixel in the test element group portion TEG. In other words, the plurality of dummy sub-pixels may include a dummy sub-optical layer shifted by a larger magnitude with an increase of its distance from the center of the test element group portion. Meanwhile, the shift magnitude of the dummy sub-optical layer in the test element group portion TEG may be the same as the shift magnitude of the sub-optical layer in the display area DAA.

According to one embodiment, the first lens 777 overlaps a plurality of sub-optical layers of the sub-pixels SP1, SP2, and SP3, while the first lens 777 does not overlap the plurality of dummy sub-optical layers DSO1, DSO2, and DSO3 of the plurality of dummy sub-pixels DPX in a plan view.

According to one embodiment, the image in the display area DAA may be indirectly inspected by analyzing light, which is provided from the dummy pixels DPX of the test element group portion TEG, by an image inspecting device 190.

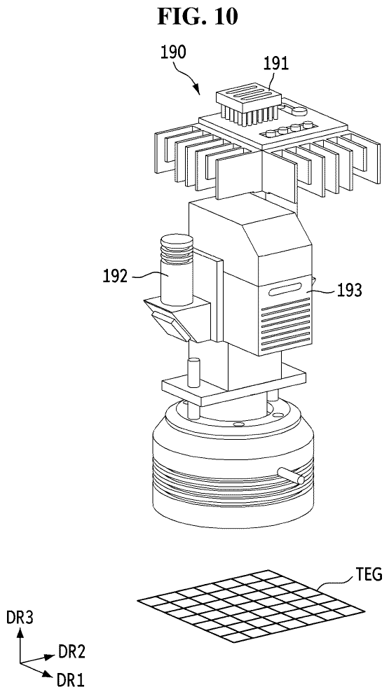

FIG. 10 is a diagram showing the image inspecting device 190 according to one embodiment.

As shown in FIG. 10, the image inspecting device 190 according to one embodiment may include a micromirror array lens module 191 (e.g., a micromirror array lens system (“MALS”)), an imaging module 192, and a controller 193.

The image inspecting device 190 may be disposed on the test element group portion TEG.

The image inspecting device 190 may receive light from the dummy pixels DPX of the test element group portion TEG. For example, light from the test element group portion TEG may be incident and reflected on a mirror lens 19 of the micromirror array lens module 191, and then provided to the imaging module 192. The imaging module 192 may generate an image based on the light provided from the micromirror array lens module 191.

The controller 193 may control the micromirror array lens module 191 and the imaging module 192. In addition, the controller 193 may analyze the image captured by the imaging module 192.

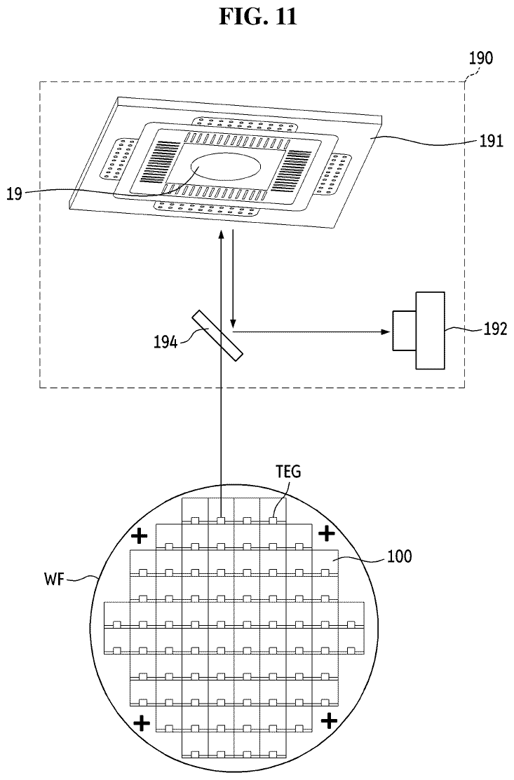

In this case, an inspection step by the image inspecting device 190 may be performed after the cover layer CVL is formed on each display panel 100 on the wafer. For example, the image inspection may be performed in a state in which the first lens 777 is not disposed. This is described in detail with reference to FIG. 11 as follows.

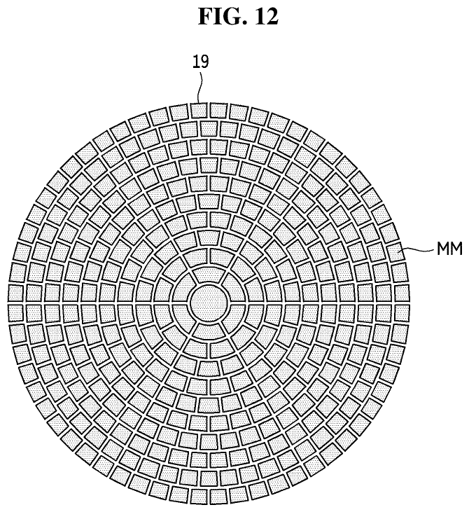

FIG. 11 is a diagram for describing an image inspection method of a display device according to one embodiment. FIG. 12 is a diagram illustrating a mirror lens of the micromirror array lens module 191 of FIG. 11.

As shown in FIG. 11, the image inspecting device 190 may include the micromirror array lens module 191, the imaging module 192, and a translucent mirror 194.

The micromirror array lens module 191 may include a circular mirror lens 19. The mirror lens 19 may include a plurality of micromirrors MM as shown in FIG. 12. The micromirrors MM may be arranged along the perimeter of the mirror lens 19 to surround the center of the mirror lens 19. The movement of each micromirror MM may be individually controlled. For example, the micromirror MM may move vertically in a direction toward the translucent mirror 194 and in the opposite direction thereto. In addition, the micromirror MM may rotate around a first axis and may rotate around a second axis that perpendicularly intersects the first axis.

The mirror lens 19 may perform the role of the aforementioned first lens 777 (e.g., a pancake lens). For example, by individually controlling the vertical position and rotation angle of each micromirror MM of the mirror lens 19, the mirror lens 19 may perform the role of a pancake lens for the test element group portion TEG. In this case, since a chief ray angle (CRA) may be changed according to the type of display panel 100 to be inspected, the controller 193 may control the position (e.g., the vertical position) and the angle (e.g., the rotation angle) of each micromirror MM of the mirror lens 19 based on the chief ray angle preset according to the type of display panel 100.

The plurality of display panels 100 may be disposed on a wafer WF. For example, the plurality of display panels 100 may be disposed in the form of a chip on the wafer.

Each display panel 100 on the wafer WF may include the test element group portion TEG. The size of the test element group portion TEG and the number of dummy pixels DPX of the test element group portion TEG may be changed according to the type of display panel 100.

The image inspecting device 190 may be disposed on the wafer WF to image the test element group portion TEG of the display panel 100. Light from the test element group portion TEG may be incident on the micromirror array lens module 191 through the translucent mirror 194. For example, light from the test element group portion TEG may be incident on the mirror lens 19 of the micromirror array lens module 191.

The light incident on the mirror lens 19 may be reflected to be incident on the translucent mirror 194. The light incident from the mirror lens 19 to the translucent mirror 194 may be reflected to be incident on the imaging module 192. The imaging module 192 may receive light through an image sensor. An image of the test element group portion TEG may be generated by light received by the imaging module 192.

The controller 193 may determine whether the display panel 100 is defective or not based on the captured image of the test element group portion TEG. Determining that the display panel 100 is defective means, for example, that the shift magnitude of the dummy sub-optical layer of the test element group portion TEG is incorrectly designed, which in turn may mean that the shift magnitude of the sub-optical layer of the display area DAA of the display panel 100 is incorrectly designed.

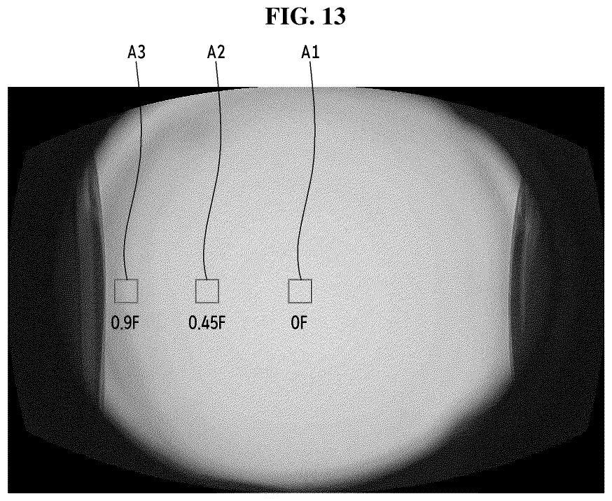

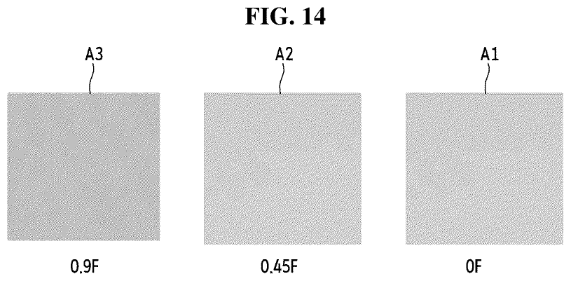

FIG. 13 is a diagram showing an image of the test element group portion TEG acquired through the image inspecting device 190 of FIG. 10. FIG. 14 shows enlarged views of first area A1, second area A2, and third area A3 in the image of FIG. 13.

In the image of FIG. 13, the image of the first area A1 refers to an image from the dummy pixel DPX in the first area A1 of FIG. 9 described above, the image of the second area A2 refers to an image from the dummy pixel DPX in the second area A2 of FIG. 9 described above, and the image of the third area A3 refers to an image from the dummy pixel DPX in the third area A3 of FIG. 9 described above. In this case, the dummy pixel DPX in the first area A1 may refer to the central dummy pixel DPX (e.g., DPX_C) located in 0 field (F), the dummy pixel DPX in the second area A2 may refer to the dummy pixel DPX in 0.45 field (F) located left of the central dummy pixel DPX, and the dummy pixel DPX in the third area A3 may refer to the dummy pixel DPX in 0.9 field (F) located far left of the central dummy pixel DPX than the second area A2.

As shown in FIGS. 13 and 14, when the deviation between the images from all the dummy pixels DPX of the test element group portion TEG including the dummy pixels DPX of the first area A1, the second area A2, and the third area A3 is less than or equal to a preset threshold value, the display panel 100 of the display device may be determined as a non-defective product. Meanwhile, when the deviation between images from all dummy pixels DPX of the test element group portion TEG is greater than the aforementioned threshold, the display panel 100 of the display device may be determined as a defective product.

For example, the image inspecting device 190 may define any one dummy pixel DPX in the captured image of the test element group portion TEG as a reference dummy pixel DPX, and individually compare the image of the reference dummy pixel DPX with each of the images of the remaining dummy pixels DPX (e.g., 24 dummy pixels DPX). For example, the color coordinates of the image of the reference dummy pixel DPX may be compared with the color coordinates of the image of the other dummy pixel DPX, and the deviation between the color coordinates may be calculated. Thereafter, in this manner, the image inspecting device 190 may set the other unselected dummy pixel DPX as the reference dummy pixel DPX, and may individually compare the selected reference dummy pixel DPX with each of the remaining dummy pixels DPX (e.g., 24 dummy pixels DPX). In this way, the image inspecting device 190 may compare the color coordinates of two of the 25 dummy pixels DPX for all combinations (e.g., 625 combinations) and calculate the deviations (e.g., 625 deviations) for all combinations. Thereafter, the image inspecting device 190 may select the maximum deviation among the deviations, and when the selected maximum deviation is less than or equal to the aforementioned threshold, the display panel 100 may be determined as a non-defective product. Meanwhile, when the selected maximum deviation is greater than the aforementioned threshold, the image inspecting device 190 may determine the display panel 100 as a defective product.

Meanwhile, according to one embodiment, the image inspecting device 190 may image the display area DAA rather than the test element group portion TEG, and may also determine whether the display panel 100 is non-defective or defective based on the captured images of the pixels in the display area DAA.

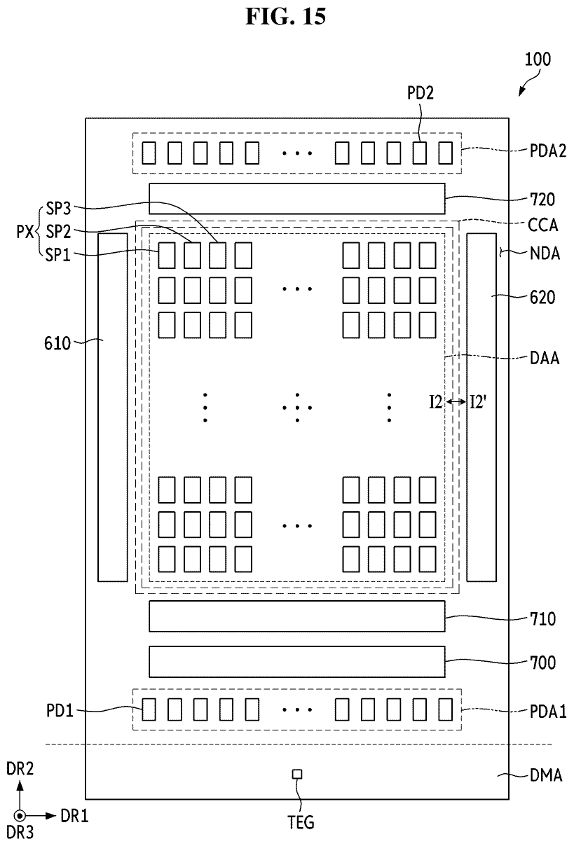

FIG. 15 is a diagram illustrating the arrangement position of the test element group portion TEG according to another embodiment.

As shown in FIG. 15, the test element group portion TEG may be disposed in a dummy area DMA of the display panel 100. The dummy area DMA of the display panel 100 may be the dummy area DMA of the wafer WF, which may be an area removed after the display panels 100 are separated from the wafer WF. For example, after the image inspection is performed on the test element group portion TEG of each display panel 100 on the wafer WF as described above, the wafer WF is cut after a cell cutting process, thereby removing the dummy area DMA of the wafer WF. In this case, as the dummy area DMA of the wafer WF is removed, the test element group portion TEG of the dummy area DMA may also be removed.

Meanwhile, after the display panels 100 are separated from the wafer WF, the first lens 777 may be disposed on the display panel 100.

According to one embodiment, since the image inspecting device 190 includes the micromirror array lens module 191 corresponding to a pancake lens, it may perform the image inspection of the display panel 100 without the first lens 777 (e.g., a pancake lens). In this case, the image inspecting device 190 may image the dummy pixels DPX of the test element group portion TEG of the display panel 100. Accordingly, an alignment operation between the display panel 100 and the first lens 777 is not necessary. Further, a collision problem between the display panel 100 and the first lens 777 that may occur during the alignment operation between the display panel 100 and the first lens 777 may also be solved.

In addition, the micromirror array lens module 191 of the image inspecting device 190 of one embodiment includes the mirror lens 19 that can be controlled based on the chief ray angle set according to the type of the display panel 100, so that image inspection may be performed without the need to prepare various first lenses 777 for each type of the display panel 100 when inspecting the image of the display panel 100.

In this way, according to one embodiment, the inspection method of the display device 10 may be simplified.

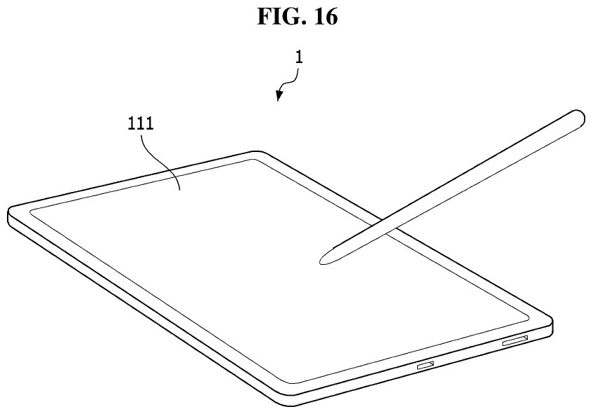

FIG. 16 is a perspective view showing an electronic device to which a display device according to one embodiment is applied.

Referring to FIG. 16, a tablet 1, to which a display device 111 according to one embodiment is applied, is illustrated as an example of an electronic device. However, the display device 111 according to one embodiment is applicable not only to the tablet 1 but also to other electronic devices. For example, the display device 111 according to one embodiment may be applied to an electronic device that displays a moving image or a still image. For example, the display device 10 according to one embodiment is applicable to portable electronic devices such as a mobile phone, a smartphone, a smartwatch, a watch phone, a mobile communication terminal, an electronic notebook, an electronic book, a portable multimedia player (PMP), a navigation device, and an ultra-mobile PC (UMPC). Alternatively, the display device 111 according to one embodiment may be used as a display screen of various electronic devices such as a television, a laptop computer, a monitor, a billboard, or an Internet-of-Things (IoT) device.

For example, the display device 111 of FIG. 16 may be the same as the aforementioned display device 10 of FIGS. 1 to 15.

The display device according to the embodiment can be applied to various electronic devices. The electronic device according to one embodiment includes the display device described above and may further include modules or devices having additional functions in addition to the display device.

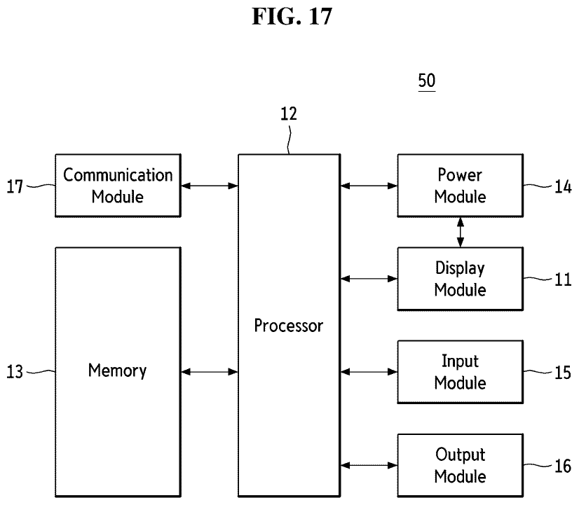

FIG. 17 is a block diagram of an electronic device according to one embodiment. Referring to FIG. 17, the electronic device 50 according to one embodiment may include a display module 11, a processor 12, a memory 13, and a power module 14. The electronic device 50 may further include an input module 15, a non-image output module 16 and/or a communication module 17.

The electronic device 50 may output various information in the form of images through the display module 11. When the processor 12 executes an application stored in the memory 13, image information provided by the application may be provided to the user through the display module 11. The power module 14 may include a power supply module such as a power adapter or a battery device, and a power conversion module that converts the power supplied by the power supply module to generate power required for the operation of the electronic device 50. The input module 15 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 50 and an external device, and may include a receiving unit and a transmitting unit.

At least one of the components of the electronic device 50 described above may be included in the display device according to the embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 50 other than the display device.

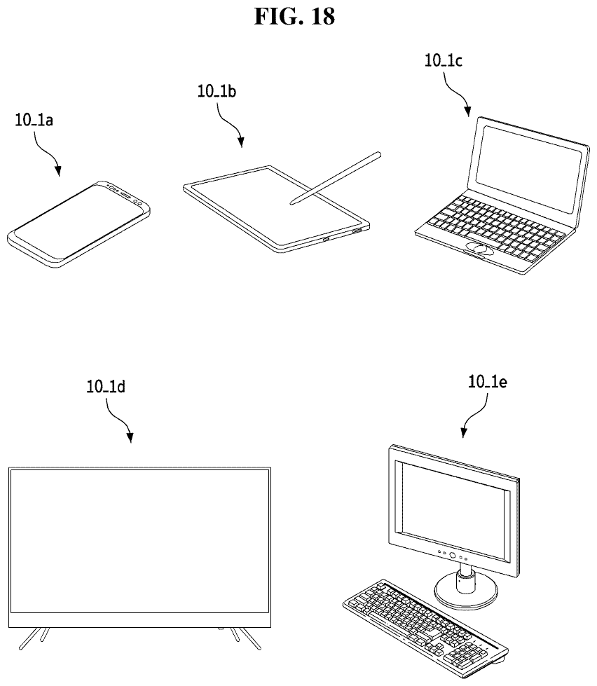

FIGS. 18, 19, and 20 are schematic diagrams of electronic devices according to various embodiments. FIGS. 18 to 20 illustrate examples of various electronic devices to which the display device according to the embodiments is applied.

FIG. 18 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

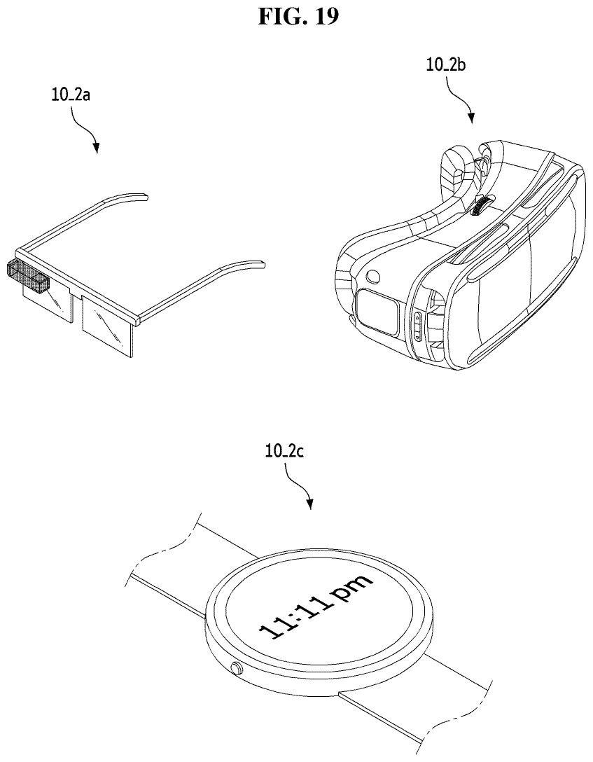

FIG. 19 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

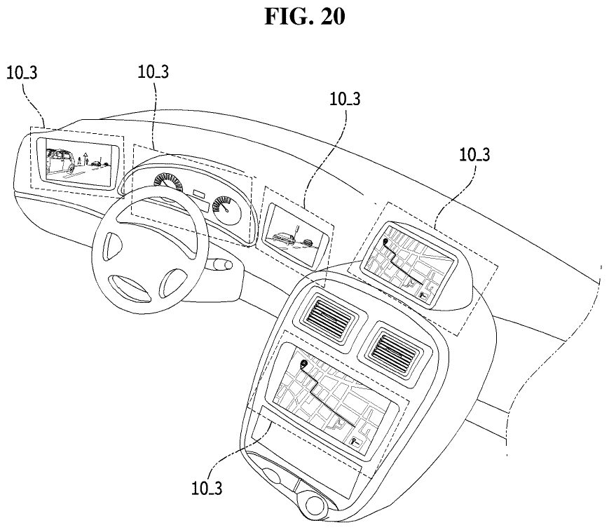

The smart watch 10_2c includes a biometric sensor as an input device, and may provide biometric information recognized by the biometric sensor to the user through the display module. FIG. 20 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a display panel having a display area in which a plurality of pixels are disposed;
a test element group portion disposed in a non-display area of the display panel and comprising a plurality of dummy pixels; and
a lens disposed on the display panel,
wherein the lens overlaps the display area and does not overlap the test element group portion.

2. The display device of claim 1, wherein each of the plurality of pixels comprises a plurality of sub-pixels,
each of the plurality of sub-pixels comprises an emission area and a sub-optical layer disposed on the emission area, and
a center of the sub-optical layer is disposed shifted from a center of the emission area by a larger magnitude in a plan view as a distance from a center of the display area to the sub-optical layer is farther in the plan view.

3. The display device of claim 2, wherein the sub-optical layer comprises:
a color filter; and
a sub-lens disposed on the color filter to overlap the color filter in the plan view.

4. The display device of claim 2, wherein the lens overlaps a plurality of sub-optical layers of the plurality of sub-pixels in the plan view.

5. The display device of claim 3, wherein the sub-lens comprises a microlens.

6. The display device of claim 2, wherein each of the plurality of dummy pixels comprises a plurality of dummy sub-pixels,
each of the plurality of dummy sub-pixels comprises a dummy emission area and a dummy sub-optical layer disposed on the dummy emission area, and
a center of the dummy sub-optical layer is disposed shifted from a center of the dummy emission area by a larger magnitude in the plan view as a distance from a center of the test element group portion to the dummy sub-optical layer is farther in the plan view.

7. The display device of claim 6, wherein the dummy sub-optical layer comprises:
a dummy color filter; and
a dummy sub-lens disposed on the dummy color filter to overlap the dummy color filter in the plan view.

8. The display device of claim 6, wherein the lens does not overlap a plurality of dummy sub-optical layers of the plurality of dummy sub-pixels in the plan view.

9. The display device of claim 1, wherein the dummy pixels of the test element group portion are disposed in the non-display area in a matrix form.

10. The display device of claim 1, wherein the display panel further comprises a pad portion, and
the test element group portion is disposed between the pad portion and an edge of the display panel.

11. An electronic device comprising a display device providing a screen,
wherein the display device comprises:
a display panel having a display area in which a plurality of pixels are disposed;
a test element group portion disposed in a non-display area of the display panel and comprising a plurality of dummy pixels; and
a lens disposed on the display panel,
wherein the lens overlaps the display area and does not overlap the test element group portion.

12. An image inspection method of a display device, comprising:
preparing a wafer having a plurality of display panels and a plurality of test element group portions disposed to correspond to the plurality of display panels, respectively;
disposing an image inspecting device on each of the test element group portions;
controlling a mirror lens of the image inspecting device based on a chief ray angle preset according to a type of a display panel of the plurality of display panels corresponding to each of the test element group portions;
imaging each of the test element group portions using the image inspecting device with the mirror lens controlled; and
determining whether the display panel is defective based on an image captured by the image inspecting device.

13. The image inspection method of claim 12, wherein the display panel comprises a plurality of pixels disposed in a display area of the display panel.

14. The image inspection method of claim 13, wherein each of the plurality of pixels comprises a plurality of sub-pixels,
each of the plurality of sub-pixels comprises an emission area and a sub-optical layer disposed on the emission area, and
a center of the sub-optical layer is disposed shifted from a center of the emission area by a larger magnitude in a plan view as a distance from a center of the display area to the sub-optical layer is farther in the plan view.

15. The image inspection method of claim 14, wherein each of the test element group portions comprises a plurality of dummy pixels.

16. The image inspection method of claim 15, wherein each of the plurality of dummy pixels comprises a plurality of dummy sub-pixels,
each of the plurality of dummy sub-pixels comprises a dummy emission area and a dummy sub-optical layer disposed on the dummy emission area, and
a center of the dummy sub-optical layer is disposed shifted from a center of the dummy emission area by a larger magnitude in the plan view as a distance from a center of a corresponding test element group portion to the dummy sub-optical layer is farther in the plan view.

17. The image inspection method of claim 15, wherein the dummy pixels of each of the test element group portions are disposed in the non-display area in a matrix form.

18. The image inspection method of claim 15, wherein the image inspecting device comprises:
a translucent mirror;
a micromirror array lens module comprising the mirror lens and which receives light from the dummy pixels through the translucent mirror; and
an imaging module, which receives light reflected from the micromirror array lens module and generates an image based on the received light.

19. The image inspection method of claim 18, wherein the mirror lens comprises a plurality of micromirrors disposed to surround a center of the mirror lens, and
positions and angles of the plurality of micromirrors are controlled based on a chief ray angle preset according to the type of the display panel corresponding to each of the test element group portions.
